(19) United States
(12) Patent Application Publication
(10) Pub. No.: US 2017/0126210 A1
(43) Pub. Date: May 4, 2017

(54) DRIVE DEVICE

(71) Applicant: DENSO CORPORATION, Kariya-city, Aichi-pref. (JP)

(72) Inventor: Kenji KOMIYA, Kariya-city (JP)

(21) Appl. No.: 15/318,390

(22) PCT Filed: Jun. 23, 2015
(86) PCT No.: PCT/JP2015/003134

§ 371 Date: Dec. 13, 2016

(30) Foreign Application Priority Data
Jul. 10, 2014 (JP) 2014-142438

(51) Int. Cl. H03K 3/012; H02M 1/08

(52) U.S. Cl. CPC H03K 3/012; H02M 1/08

(57) ABSTRACT

A drive device includes a main power supply coupled to a driver circuit for controlling on and off of a switching element; a first capacitor coupled, in parallel with the driver circuit, to the main power supply and disposed with no element other than wiring interposed between the first capacitor and the driver circuit; and an impedance element coupled, in series with the first capacitor and the driver circuit, to the main power supply and disposed with no element other than wiring interposed between the impedance element and the first capacitor and between the impedance element and the driver circuit. Electrostatic capacitance C₁ of the first capacitor satisfies the following relationship with respect to gate capacitance Cgs of the switching element and intermediate potential Vdr present between the driver circuit and the impedance element in a state of the first capacitor being fully charged:

$$\frac{{V}_{th}}{{V}_{dr} - {V}_{th}} {C}_{gs} < {C}_{1} < 9 {C}_{gs}$$

### CROSS REFERENCE TO RELATED APPLICATIONS

This application is a U.S. national stage application of International Patent Application No. PCT/JP2015/003134 filed on Jun. 23, 2015 and is based on Japanese Patent Application No. 2014-142438 filed on Jul. 10, 2014, the disclosures of which are incorporated herein by reference.

### TECHNICAL FIELD

The present disclosure relates to a drive device to supply voltage to a driver circuit which drives a switching element.

### BACKGROUND

A driver circuit to drive a switching element is demanded to be capable of faster switching so as to reduce switching loss. However, increasing the switching speed generates problems such as EMI (electromagnetic interference) noise and surges. To be concrete, ringing of the output current of the switching element occurs.

To solve the problem, a gate driver circuit is proposed in patent literature 1 which includes a current source circuit for discharging gate charges when turning off the current flowing through the main terminal of the switching element. A current adjustment circuit is also provided which, by controlling the current source circuit as the voltage across the main terminal of the switching element increases, gradually discharges the gate charges. This makes it possible to effectively reduce both surges and turn-off loss regardless of switching element variations associated with manufacture and switching element operating conditions.

In patent literature 2, a driver circuit is proposed which, immediately after a switching element is turned off, uses two discharge paths to discharge gate charges, then automatically decreases the discharge paths to one as the drain voltage lowers. To realize the above structure, the driver circuit having no discharge structure is provided with two MOSFETs and one mono-stable multi-vibrator circuit.

### PATENT LITERATURE

Patent Literature 1: JP 2008-67593 A

Patent Literature 2: JP 2001-45740 A

### SUMMARY

However, the driver circuits disclosed in the above two patent literatures have no discharging structure and are each added to by a relatively large-scale circuit. This causes a problem that the overall circuit scale of each drive device for a switching element becomes large. In addition, providing a special additional circuit results in a cost increase.

It is an object of the present disclosure to provide a drive device which, having a simpler configuration, can achieve both faster switching and ringing suppression.

According to an aspect of the present disclosure, the drive device supplies voltage to a driver circuit to control turning on and off of a switching element and includes: a main power supply coupled to the driver circuit; a first capacitor coupled, in parallel with the driver circuit, to the main power supply and disposed with no element other than wiring interposed between the first capacitor and the driver circuit; and an impedance element coupled, in series with the first capacitor and the driver circuit, to the main power supply and disposed with no element other than wiring interposed between the impedance element and the first capacitor and between the impedance element and the driver circuit. In the drive device, electrostatic capacitance C₁ of the first capacitor satisfies the relationship of Expression 1 with respect to gate capacitance Cgs of the switching element and intermediate potential Vdr present between the driver circuit and the impedance element in a state of the first capacitor being fully charged.

$$\frac{{V}_{th}}{{V}_{dr} - {V}_{th}} {C}_{gs} < {C}_{1} < 9 {C}_{gs} \qquad [ Expression 1 ]$$

The charges, which are accumulated in the first capacitor when the switching element is in an off state, start to be injected into the gate of the switching element at the same time as the driver circuit starts operation to turn the switching element on. The charges of the first capacitor, which decreases with the injection into the gate, are supplemented by the main power supply. An impedance element having a predetermined value of impedance is disposed between the first capacitor and the main power supply. This delays the transfer of charges from the main power supply to the first capacitor. Thus, the intermediate potential present between the driver circuit and the impedance element starts decreasing at the same time as the driver circuit starts operation to turn the switching element on. In other words, the voltage applied to the gate of the switching element starts decreasing.

As described above, since the first capacitor and the impedance element are provided, at the same time as the driver circuit starts operation to turn the switching element on, the driving capability of the driver circuit is caused to lower. Therefore, in a driver circuit for a switching element required to make high-speed switching, output current ringing can be suppressed without requiring a relatively large-scale circuit to discharge charges which is required in the cases disclosed in patent literature 1 and 2.

By satisfying the relationship expressed by Expression 1, the voltage applied to the gate of the switching element can be kept higher than a threshold voltage. Moreover, immediately after operation to turn the switching element on is started by the driver circuit, the switching element can be driven in a state where the gate potential has lowered at least 10% with respect to intermediate potential Vdr present between the driver circuit and the impedance element. Thus, a minimum gate potential required to drive the switching element can be applied, so that the driving capability of the driver circuit can be lowered when the switching element is turned on.

### BRIEF DESCRIPTION OF DRAWINGS

The above and other objects, features and advantages of the present disclosure will become more apparent from the following detailed description made with reference to the accompanying drawings, in which:

FIG. 1 is a circuit diagram showing a drive device and peripheral circuits of the drive device according to a first embodiment; and

FIG. 2 is a diagram showing temporal variations in drain current and drive voltage.

### DETAILED DESCRIPTION

In the following, an embodiment of the present disclosure will be described based on the drawings. In the drawings referred to in the following, mutually identical or equal parts are denoted by identical reference symbols.

### First Embodiment

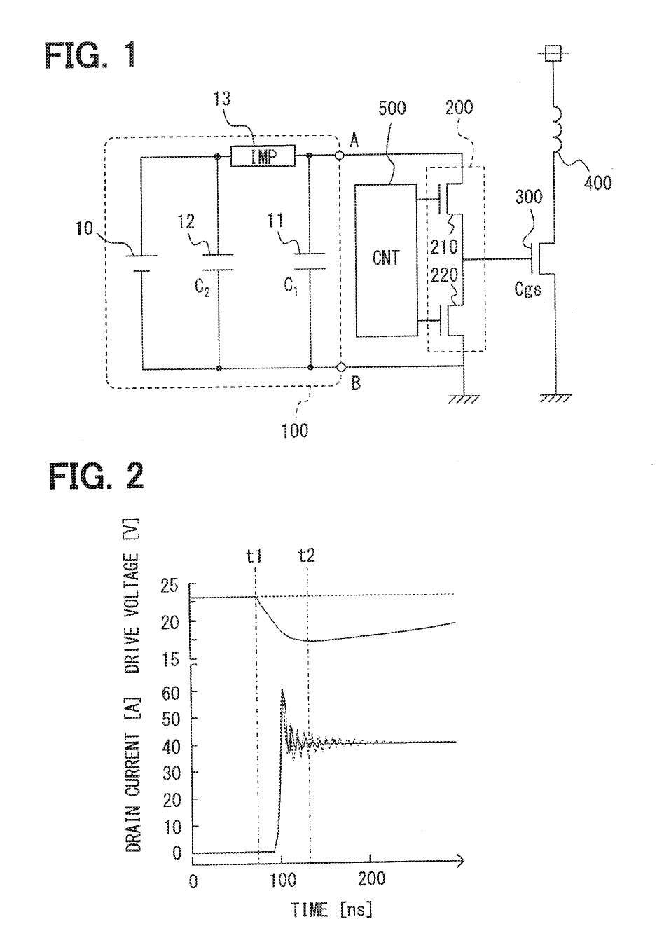

First, an outline configuration of a drive device according to the present embodiment will be described with reference to FIG. 1.

As shown in FIG. 1, the drive device 100 is a power supply device to supply voltage to a driver circuit 200 and to eventually apply voltage to the gate of a switching element 300. The driver circuit 200 controls turning on/off of the switching element 300 based on control signals output from a control unit (CNT) 500 so as to control the amount of current flowing through a load 400. The switching element 300 of the present embodiment is assumed to be a power MOS transistor.

The drive device 100 includes a main power supply 10, a first capacitor 11, a second capacitor 12 and an impedance element (IMP) 13.

The main power supply 10 supplies voltage to the driver circuit 200. The main power supply 10 is a DC power supply to generate voltage to be applied to the gate of the switching element 300.

The first capacitor 11 is coupled to the main power supply 10 in parallel with the driver circuit 200. The first capacitor 11 is disposed immediately before terminals A and B which are output terminals of the drive device 100, and both ends of the first capacitor 11 and both ends of the driver circuit 200 are mutually coupled with no element other than wiring interposed between them.

The second capacitor 12 is coupled to the main power supply 10 in parallel with the first capacitor 11. The second capacitor 12 operates as a smoothing capacitor to smooth voltage fluctuation attributable to, for example, elements, not shown, disposed between the second capacitor 12 and the main power supply 10.

The impedance element 13 is, for example, a resistor and is coupled between the main power supply 10 and the first capacitor 11 such that the impedance element 13 and the first capacitor 11 are series-coupled to the main power supply 10. In other words, with respect to the impedance element 13, the first capacitor 11 and the driver circuit 200 are parallel-coupled. The impedance element 13 is coupled to the positive side of the main power supply 10. With respect to the main power supply 10, the second capacitor 12 and the impedance element 13 are parallel-coupled with no element other than wiring interposed between the second capacitor 12 and the impedance element 13.

In the present embodiment, of the output terminals of the drive device 100, terminal B on the lower potential side is used as ground (GND). Also, the potential of terminal A on the higher-potential side in a state with the first capacitor 11 fully charged is denoted as Vdr. Vdr is the potential equaling the voltage across the main power supply 10 less the voltage drop caused by the impedance element 13.

The driver circuit 200 has a configuration in which an on-side switch 210 and an off-side switch 220 are coupled in series. One end of the on-side switch 210 is coupled to terminal A of the drive device 100, and one end of the off-side switch 210 is coupled to terminal B. The gate of the switching element 300 is coupled to a midpoint between the on-side switch 210 and the off-side switch 220. In the present embodiment, the on-side switch 210 and the off-side switch 220 are MOS transistors.

When turning the switching element 300 on, the control unit 500 outputs a control signal to turn the on-side switch 210 on and the off-side switch 220 off. As a result, a voltage equaling the voltage at terminal A of the drive device 100 is applied to the gate of the switching element 300, causing the switching element 300 to turn on. When, meanwhile, turning the switching element 300 off, the control unit 500 outputs a control signal to turn the on-side switch 210 off and the off-side switch 220 on. As a result, the potential of the gate of the switching element 300 becomes a GND potential the same as the potential of terminal B of the drive device 100. This causes the charges present at the gate of the switching element 300 to be removed and turns the switching element 300 off.

Electrostatic capacitance C₁ of the first capacitor 11 satisfies the relationship of Expression 7 with respect to gate capacitance Cgs of the switching element 300, threshold voltage Vth of the switching element 300, and the above-mentioned Vdr.

Next, the operation and effect of the drive device 100 of the present embodiment will be described with reference to FIGS. 1 and 2. FIG. 2 is a diagram illustrating results of circuit simulation performed by the inventor.

A case in which the switching element 300 changes, after being in an off state for an adequately long period of time, to an on state will be described.

When the switching element 300 is in an off (a state before time t1 shown in FIG. 2), the control unit 500 keeps, as described above, the on-side switch 210 off and the off-side switch 220 on. In the state, the potential (=drive voltage) of terminal A is Vdr. Namely, the drive voltage equals the potential represented by the voltage across the main power supply 10 less the voltage drop caused by the impedance element 13.

At time t1, the control unit 500 outputs to the driver circuit 200 a control signal to turn the switching element 300 on. As a result, the on-side switch 210 turns on and the off-side switch 220 turns off. In a prior-art configuration including neither the first capacitor 11 nor the impedance element 13, the drive voltage is kept at a fixed level defined by the main power supply 10 as shown in a dotted line in FIG. 2. In such a configuration, the voltage defined by the main power supply is kept applied to the gate of the switching element 300. This allows a sharp drain-current increase to cause ringing.

In the present embodiment, on the other hand, the drive device 100 includes the first capacitor 11 and the impedance element 13. When, at time t1, the on-side switch 210 is turned on and the off-side switch 220 is turned off, the gate is applied with the drive voltage Vdr. Subsequently, the charges accumulated in the first capacitor 11 start being injected into the gate of the switching element 300 and decrease. The decrease in the charges accumulated in the first capacitor 11 are supplemented by the main power supply 10 or second capacitor 12. Since the impedance element 13 is disposed on the current path to the first capacitor 11, the discharging speed exceeds the charging speed for the first capacitor 11. Hence, after time t1, the drive voltage decreases. Subsequently, when, at time t2, for the first capacitor 11, the discharging speed decreases to below the charging speed, the charges start being accumulated in the first capacitor 11 causing the drive voltage to increase.

In this way, at time t1, a maximum drive voltage defined by the main power supply 10 and the impedance element 13 can be applied to the gate of the switching element 300. Therefore, rising of the drain current, i.e. di/dt, can be made almost equivalent to rising of the drain current in a prior-art configuration. In other words, high-speed switching can be realized.

Moreover, since, as described above, the drive voltage can be decreased from immediately after time 1, the driving capability of the driver circuit 200 can be temporarily decreased to suppress di/dt. Therefore, as shown in a solid line in FIG. 2, drain current ringing can be suppressed.

Next, electrostatic capacitance C₁ of the first capacitor 11 will be quantitatively described.

In the following, the gate capacitance of the switching element 300 will be denoted as Cgs and the drive voltage after time t1 will be denoted as V(t).

The total amount of charges is unchanged before and after time t1, so that Expression 4 holds.

C₁V_{dr}=(C₁+C_{gs})V(t) [Expression 4]

V(t) is required to be always larger than threshold voltage Vth of the switching element 300. Therefore, when Expression 4 is solved for V(t) and a relationship of V(t)>Vth is applied, Expression 5 is established.

$${C}_{1} > \frac{{V}_{th}}{{V}_{dr} - {V}_{th}} {C}_{gs} \qquad [ Expression 5 ]$$

When V(t) decreases with respect to Vdr even only slightly, the driving capability is expected to decrease. For example, V(t) can be made to become smaller than 90% of Vdr by solving Expression 4 for V(t) and applying V(t)<0.9Vdr. This establishes Expression 6.

C₁<9C_{gs} [Expression 6]

Thus, the above-described operation and effect can be realized by satisfying the relationship of Expression 7 for electrostatic capacitance C₁ of the first capacitor 11 with respect to gate capacitance Cgs of the switching element 300 and intermediate potential Vdr present between the driver circuit 200 and the impedance element in a state of the first capacitor 11 being fully charged.

$$\frac{{V}_{th}}{{V}_{dr} - {V}_{th}} {C}_{gs} < {C}_{1} < 9 {C}_{gs} \qquad [ Expression 7 ]$$

Next, the impedance of the impedance element 13 will be quantitatively described.

The following description of the present embodiment is based on the assumption that the impedance element 13 is a resistor with a resistance value R. In the following description, values of electrostatic capacitance, resistance and frequency will be represented in units of F, Ω and Hz, respectively.

First, a lower limit value of resistance R will be considered. To realize the above-described operation and effect, it is necessary to suppress the driving capability of the driver circuit 200 during a transition period in which the drain current rises. The driving capability is low while the charges in the first capacitor 11 have not reached an amount of charges defined by the electrostatic capacitor C₁. In other words, the time for charging the first capacitor 11 is required to be longer than the switching time, i.e. the time taken after the drain current starts rising until the rising is completed.

The charging time for the first capacitor 11 is about e times the charging time constant (=C₁R), where e is a Napier's constant. Therefore, when a minimum switching time is assumed to be 10 ns, the relationship of eC₁R>10×10⁻⁹ is established, and this can be arranged to establish Expression 8.

$$R > \frac{1}{e {C}_{1}} \times {10}^{- 8} \qquad [ Expression 8 ]$$

Next, an upper limit value of resistance R will be considered. The switching element 300 periodically turns on and off at a predetermined frequency in synchronization with the turning on and off of the on-side switch 210 of the driver circuit 200. The drive voltage starts decreasing with respect to Vdr after the on-side switch 210 is turned from on to off and is required to rise back to Vdr before the on-side switch 210 is turned on again.

The time taken after the on-side switch 210 turns from on to off until turning on again can be expressed as (1−D)/f, where f is a carrier frequency, i.e. the drive frequency of the switching element 300, and D is a duty ratio. Thus, the relationship with the charging time (=eC₁R) for the first capacitor 11 can be expressed by Expression 9.

$$R < \frac{1}{e {C}_{1}} \frac{1 - D}{f} \qquad [ Expression 9 ]$$

From what has been described above, resistance R [Ω] of the impedance element 13 is preferably set to satisfy the relationship of Expression 10 with respect to electrostatic capacitance C₁ [F] of the first capacitor 11, carrier frequency f [Hz] and duty ratio D.

$$\frac{1}{e {C}_{1}} \times {10}^{- 8} < R < \frac{1}{e {C}_{1}} \frac{1 - D}{f} \qquad [ Expression 10 ]$$

(Modification)

The impedance element 13 may be other than a resistor, for example, a coil with self-inductance L. In the following description, electrostatic capacitance, self-inductance and frequency will be represented in units of F, H and Hz, respectively. Moreover, e represents a Napier's constant and it represents a circular constant.

First, a lower limit value of self-inductance L will be considered. For the present modification, charging time constant C₁R of the first capacitor 11 used in the foregoing first embodiment is replaced by 2π(C₁L)^{1/2}. Namely, self-inductance L preferably satisfies Expression 11.

$$L > \frac{1}{{( 2 πe )}^{2} {C}_{1}} \times {10}^{- 16} \qquad [ Expression 11 ]$$

Next, an upper limit value of self-inductance L will be considered. For the upper limit value, too, charging time constant C₁R of the first capacitor 11 used in the foregoing first embodiment is replaced by 2π(C₁L)^{1/2}. Namely, self-inductance L preferably satisfies Expression 12.

$$L > \frac{1}{{( 2 πe )}^{2} {C}_{1}} {( \frac{1 - D}{f} )}^{2} \qquad [ Expression 12 ]$$

From what has been described above, self-inductance [H] of the impedance element 13 is preferably set to satisfy the relationship of Expression 13 with respect to electrostatic capacitance C₁ [F] of the first capacitor 11, carrier frequency f [Hz] and duty ratio D.

$$\frac{1}{{( 2 πe )}^{2} {C}_{1}} \times {10}^{- 16} < L < \frac{1}{{( 2 πe )}^{2} {C}_{1}} {( \frac{1 - D}{f} )}^{2} \qquad [ Expression 13 ]$$

### Other Embodiments

An embodiment of the present disclosure has been described, but the present disclosure is not limited to the above embodiment and can be modified in various ways without departing from the scope of the disclosure.

For the above embodiment, it has been described that electrostatic capacitance C₁ of the first capacitor 11 preferably satisfies Expression 7. In this regard, there are cases in which, even when the expression of drive voltage V(t)>Vth is satisfied, if the value of V(t) is in the vicinity of Vth, rising of the drain current, i.e. di/dt, becomes too small, causing the switching loss to be greatly aggravated. Moreover, when the ratio of decrease of V(t) with respect to Vdr is reduced from 90% to about 50%, enhancement of the ringing suppression effect can be expected. Namely, electrostatic capacitance C₁ preferably satisfies Expression 14.

$$\frac{{V}_{th} + {V}_{0}}{{V}_{dr} - {V}_{th}} {C}_{gs} < {C}_{1} < 5 {C}_{gs} \qquad [ Expression 14 ]$$

In Expression 14, V₀ is a constant satisfying the relationship of 1<V₀<20. When electrostatic capacitance C₁ satisfies the relationship of C₁<3Cgs, a further effect of ringing suppression can be expected.

For the foregoing embodiment, it has been described concerning the lower limit value of resistance R that resistance R preferably satisfies Expression 8. This is based on the assumption that a minimum switching time is 10 ns. There are cases in which, when the switching element 300 with a switching time longer than 10 ns is used, an adequate charging time cannot be secured. Also, it has been described concerning the upper limit value of resistance R that resistance R preferably satisfies Expression 9. This indicates that the charging time (=eC₁R) of the first capacitor 11 is shorter than the time (1−D)/f taken after the on-side switch 210 turns from on to off until turning on again. In the case of (1−D)/f≈eC₁R, however, there are cases in which the voltage across the first capacitor 11 after being charged is not stable. Hence, resistance R preferably satisfies Expression 15 so as to be effective also for the switching element 300 with a switching time longer than 10 μs and so as to adequately stabilize the voltage across the first capacitor 11.

$$\frac{1}{e {C}_{1}} \times {10}^{- 6} < R < \frac{1}{e {C}_{1}} \frac{1 - D}{f} \times 0.1 \qquad [ Expression 15 ]$$

Also, for the foregoing embodiment and the modification of the embodiment, a configuration with the drive device 100 having the second capacitor 12 has been described, but the foregoing operation and effect can be realized even when the second capacitor 12 is not included in the configuration. However, since the second capacitor 12 smooths voltage fluctuation occurring in an optional circuit formed between the main power supply 10 and the second capacitor 12, the second capacitor 12 is preferably included in the configuration.

Also, for the foregoing embodiment and the modification of the embodiment, the driver circuit 200 has been described as being configured with two MOS transistors, but the drive device 100 can also be applied to a driver circuit of a different type.

Also, for the foregoing embodiment and the modification of the embodiment, the switching element 300 has been described as a power MOS transistor. However, the switching element 300 is not limited to a power MOS transistor, and the drive device 100 can also be applied to a switching element 300 of a different type, for example, an insulated-gate bipolar transistor (IGBT). Furthermore, the drive device 100 can also be applied to, for example, a GaN high electron mobility transistor (HEMT) or SiC MOSFET.

The present disclosure has been described based on the embodiments, but it is to be understood that the present disclosure is not limited to the embodiments and configuration described above. The present disclosure embraces various modifications including modifications falling within an equivalent scope. Furthermore, various combinations and aspects, and also other combinations and aspects including only an element or less than an element or more than an element of such various combinations and aspects are also included in the scope and idea of the present disclosure.

1. A drive device that supplies voltage to a driver circuit to control turning on and off of a switching element, comprising:
a main power supply coupled to the driver circuit;
a first capacitor coupled, in parallel with the driver circuit, to the main power supply and disposed with no element other than wiring interposed between the first capacitor and the driver circuit; and
an impedance element coupled, in series with the first capacitor and the driver circuit, to the main power supply and disposed with no element other than wiring interposed between the impedance element and the first capacitor and between the impedance element and the driver circuit,
wherein electrostatic capacitance C₁ of the first capacitor satisfies a relationship of Expression 1 with respect to gate capacitance Cgs of the switching element, intermediate potential Vdr present between the driver circuit and the impedance element in a state of the first capacitor being fully charged, and threshold voltage Vth of the switching element:
$$\frac{{V}_{th}}{{V}_{dr} - {V}_{th}} {C}_{gs} < {C}_{1} < 9 {C}_{gs} \qquad [ Expression 1 ]$$

2. The drive device according to claim 1, wherein the impedance element is a resistor.

3. The drive device according to claim 2, wherein resistance R [Ω] of the resistor satisfies a relationship of Expression 2 with respect to the electrostatic capacitance C₁ [F] of the first capacitor, carrier frequency f [Hz], duty ratio D, and Napier's constant e:
$$\frac{1}{e {C}_{1}} \times {10}^{- 8} < R < \frac{1}{e {C}_{1}} \frac{1 - D}{f} \qquad [ Expression 2 ]$$

4. The drive device according to claim 1, wherein the impedance element is a coil.

5. The drive device according to claim 4, wherein self-inductance L [H] of the coil satisfies a relationship of Expression 3 with respect to the electrostatic capacitance C₁ [F] of the first capacitor, carrier frequency f [Hz], and duty ratio D:
$$\frac{1}{{( 2 πe )}^{2} {C}_{1}} \times {10}^{- 16} < L < \frac{1}{{( 2 πe )}^{2} {C}_{1}} {( \frac{1 - D}{f} )}^{2} \qquad [ Expression 3 ]$$

6. The drive device according to claim 1, comprising a second capacitor coupled, in parallel with the impedance element, to the main power supply and disposed with no element other than wiring interposed between the second capacitor and the impedance element.
